(19) United States
(12) Patent Application Publication
(10) Pub. No.: US 2012/0090890 A1
(43) Pub. Date: Apr. 19, 2012

(54) RAPIDLY SELF-DRYING RECTIFYING FLAME ROD

(75) Inventors: Kurt Kraus, Tulsa, OK (US); Dusty Richmond, Cleveland, OK (US); Matthew Martin, Tulsa, OK (US)

(73) Assignee: HONEYWELL INTERNATIONAL INC., Morristown, NJ (US)

(21) Appl. No.: 12/905,309

(22) Filed: Oct. 15, 2010

(51) Int. Cl. H02G 3/00; H05K 13/00

(52) U.S. Cl. 174/70 R; 29/592.1

(57) ABSTRACT

An assembly for a rapidly-drying rectifying flame rod, having an insulator sleeve. The assembly may further incorporate a mechanical coupling attaching the flame rod to an end part which in turn may be hermetically coupled to an insulator. The insulator may be hermetically coupled to a conduit which may be hermetically coupled to an elongated tube. A conductor may go through the tube, conduit, insulator and end part. The flame rod may be connected to the conductor via the mechanical coupling and end part. A sheath having sealing and electrical insulating properties may be formed over at least a portion of the components. Hermetic couplings may be made with ordinary blazing or welding. The couplings may instead be made with high temperature brazing or welding which can withstand temperatures equal to or greater than 1500° F. At these temperatures, the sleeve on the flame rod and the sheath may be eliminated.

### BACKGROUND

The present disclosure pertains to flame sensing and particularly to mechanisms for detecting flames.

### SUMMARY

This disclosure reveals an assembly for a rapidly-drying rectifying flame rod. An insulator sleeve may cover a portion of the flame rod. A coupling may attach the flame rod to an end part. An insulator may be hermetically attached to the end part. A conduit may be hermetically attached to the insulator and an elongated tube may be hermetically attached to the conduit. A conductor may go through the elongated tube, the conduit, the insulator and be connected to the end part. The flame rod may be electrically connected to the conductor via the coupling and the end part. A sheath having sealing and electrical insulating properties may be formed over a portion of the elongated tube, the conduit, the insulator, the end part, and at least a portion of the coupling or alternatively all of the coupling and a portion of the sleeve. The hermetic attachments may be made with ordinary blazing or welding. However, the attachments may instead be made with high temperature brazing or welding which become durable at temperatures equal to or greater than 1500 degrees F. At these temperatures, the sleeve on the flame rod and the sheath coating may be eliminated.

### BRIEF DESCRIPTION OF THE DRAWING

FIG. 1 is a basic diagram of a flame sensor of the present disclosure;

FIG. 2 shows diagrams of a structure of the flame sensor for reduction of detrimental factors that may affect the sensor;

FIG. 3 is a sectional diagram showing an illustrative example of particular a component arrangement for the flame sensor;

FIG. 4 is a diagram of an external view of the sensor component arrangement shown in FIG. 3;

FIG. 5 is a diagram showing an overall flame sensor assembly;

FIG. 5a is a diagram like that of FIG. 5 but showing an external sheathing and a high temperature ceramic insulator sleeve;

FIG. 6 is a diagram of the flame rod assembly as placed in a burner pilot tube; and

FIG. 7 is a diagram of the flame rod assembly having a higher temperature resistant design and situated in a position closer to the flame area than the rod assembly in the diagram of FIG. 6.

### DESCRIPTION

The present assembly may have a conductor, an insulator situated around the conductor, an end part formed on an end of the insulator and situated around the conductor, and a flame rod attached to the end part via a coupling. There may be an insulator covering a portion of the flame rod. The end part may be hermetically sealed to the other insulator at perimeters of the insulator and the end part. A conductor end may seal an end of the end part and make electrical contact via the coupling with the flame rod. There may also be a conduit situated around the conductor and hermetically sealed to the other end of the insulator. There may be a hermetic sealed connection of an elongated tube to the conduit. A sheath may cover a portion of the elongated tube, all of the conduit, the insulator, the end part and a portion of the insulator on the flame rod. The combined volume of the insulator, end part, housing, fitting and tube may be hermetically sealed from an external ambient environment. Moisture may short circuit the flame rod to ground of the burner structure and prevent the flame rod's capability to detect a flame. The insulator of the assembly may support and electrically isolate the flame rod from ground to prevent or reduce a possibility of an electrical short circuit. The flame rod may be in contact with the flame. The flame may include an ionized gas field that causes an electrical potential between the flame and ground which may be detected. The hermetically sealed connections between the elongated tube and the conduit, between the conduit and the insulator, and between the insulator and the end part may be effected with ordinary brazing or welding. Alternatively, the hermetically sealed connection may be effected with high temperature (1500° F.) brazing or welding. Such connection made with high temperature brazing or welding means that the connection can withstand a temperature of 1500° F. High temperature brazing or welding may also mean that the resulting connection can withstand direct exposure to and direct immersion in a burner flame. With the high temperature connections, the sheath and the insulator covering the portion of the flame are not necessarily needed.

The present apparatus may resolve an issue of a rectifying flame rod becoming inoperable due to moisture or water causing a short circuit across the flame rod's insulator by preventing the insulator from becoming wet and, if wet, drying very quickly, even virtually instantaneous. The insulator may be used to support and electrically isolate the rectifying flame rod from earth ground of the burner's metal construct, which can become wet in a normal service environment thus causing an electrical short circuit across the insulator. The short circuit may render inoperable the flame detection function of the flame rod and associated flame amplifier.

Rectifying flame rods may be used to indicate the presence or absence of a flame on a burner. When a flame is emitted by a metal burner, the combustion process may create and move a field of ionized gas as part of the burner flame. A flame rod may be positioned so as to be in intimate fluid contact with and be at least partially immersed in the flame. An effect of the moving ionized gas field in the flame over the flame rod is to create an electrical potential between the metal burner and the flame rod that can be detected by the flame rod in conjunction with a flame amplifier module. One example of many various commercially available flame amplifier modules may be a Model FSP5075A by Honeywell International Inc. of Morristown, N.J.

Detecting the presence and absence of a flame is a primary purpose of a flame amplifier module which has an input connected to the flame rod. The flame rod and the amplifier may be incorporated into a burner management system. Flame detection is regarded as necessary in a burner management system since the system may regulate and control logical steps that ensure proper and safe operation, light-off, continuous operation, modulation, and shut down of a burner.

The present flame rod structure and apparatus may prevent moisture or water from causing a short circuit across the flame rod's insulator by one or more of the following: 1) utilizing a hermetically sealed insulator to isolate the flame rod from external water and terminate the electrical conducting wire that is connected to the flame amplifier; 2) sealing an outer surface of the hermetically sealed insulator with an electrically insulating sheath of an extended length to reduce the possibility of a short circuit occurring across the length of the electrically insulating sheath; 3) supporting the flame rod with a ceramic insulator capable of withstanding direct exposure to and direct immersion in the burner flame so as to be dried immediately by the flame if wetted by moisture or water from the environment; and 4) positioning a support contact between the burner metal structure and the high temperature (1500° F.) ceramic insulator where it may be dried immediately by heat from the burner flame.

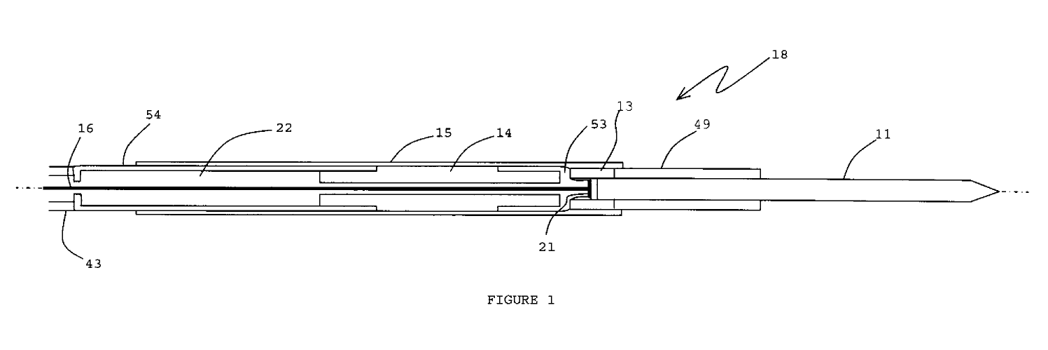

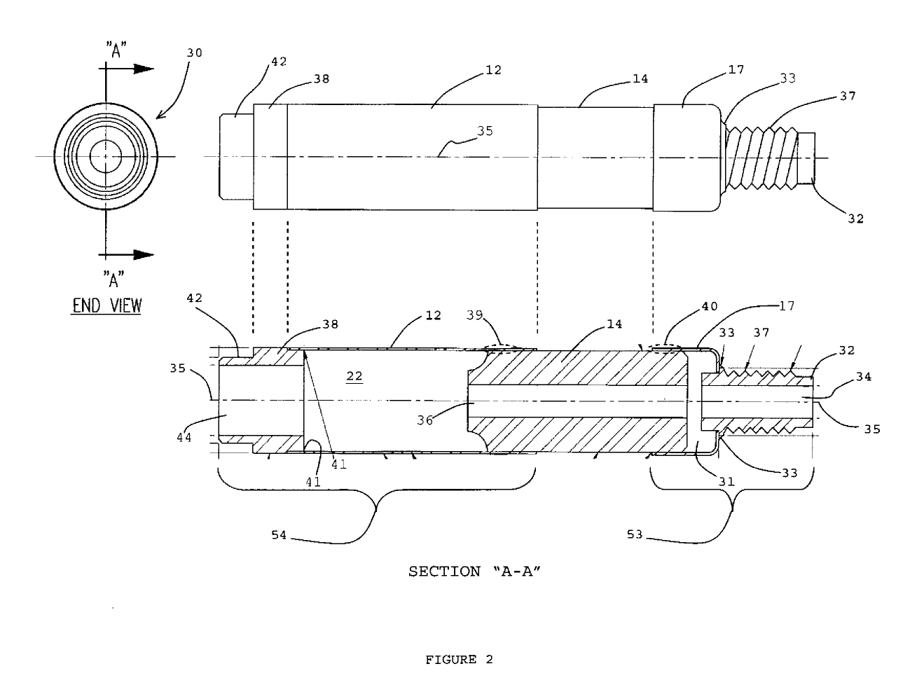

To make a flame rod device, which may overcome various disadvantages of a conventional flame rod device, the present flame rod assembly 18 may be provided, as shown by diagram in FIG. 1. The diagram of a side cut-away view of assembly 18 showing an insulator 14 and associated components. Insulator 14 may be composed of, for example, high alumina content ceramic, mullite, steatite, or other similar materials. Towards one end of a conduit 54 and conductor or wire 16 is insulator 14. Between insulator 14 and the end of a conductor housing portion of conduit 54 and conductor or wire 16 may be a volume 22. Assembly 18 may have components round and concentric to one another. However, one or more components of assembly 18 may have various shapes and not necessarily be round and concentric relative to one another, as shown in end view 30 of FIG. 2.

The flame rod assembly 18 may consist of the flame rod 11, usually made from a material called Kanthol (or Kanthal) but could be made from other like materials, such as stainless steel, Inconel™, hastaloy, or Hastelloy™. In FIG. 2, there may be a cap 17 and a fixture 32 which has threads 37. However, cap 17 and fixture 32 may be fabricated or machined as one piece forming an end part 53. The fixture 32 portion of end part 53 and its threads may extend out from insulator 14 and the cap 17 portion.

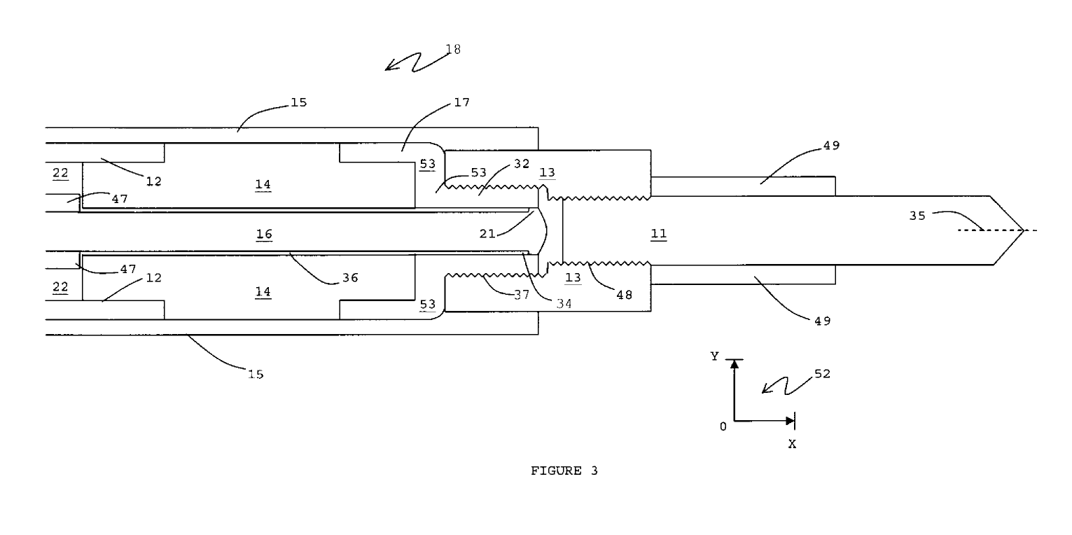

In FIG. 3, a coupling 13 having threads on one end for threads 37 of the fixture 32 portion and having threads on the other end for threads 48 on the flame rod 11 may couple mechanically and electrically end part 53 and rod 11 to each other via screwed connections. Threads 37 and 48 may be left-or right-hand threads. Hermetic sealing is not necessarily provided by the thread connections between coupling 13 and the fitting 32 portion of part 53 and between flame rod 11 and coupling 13. End part 53 and coupling 13 may be composed of stainless steel, or other similar materials.

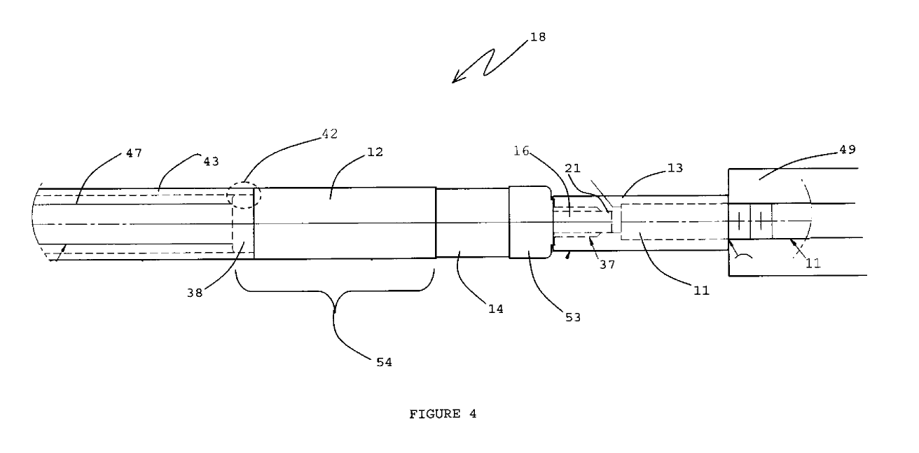

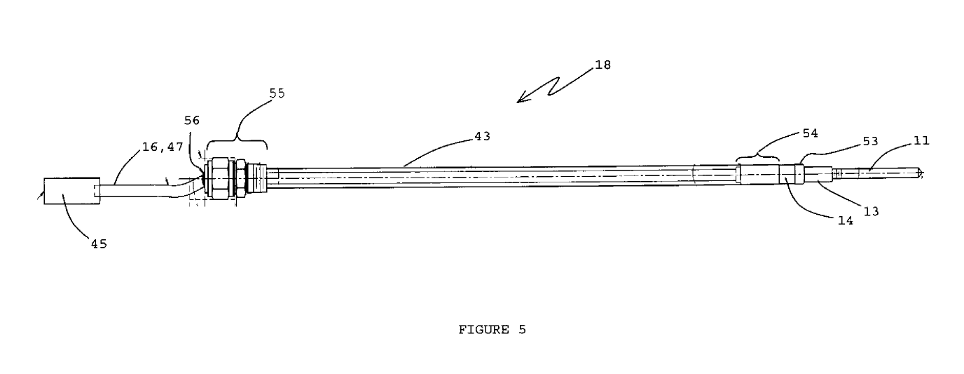

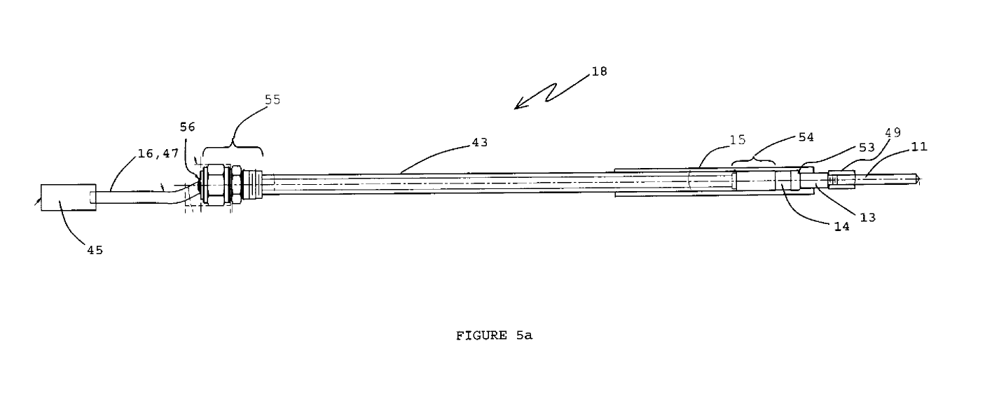

An electrical connection may be made with a conductor 16. The end of conductor 16 towards the flame rod 11 may hermetically seal off a hole 34 of the fixture 32 portion of end part 53 with a braze or weld 21 at the end proximate to the flame rod. Insulator cap 17 portion of end part 53 may be brazed or welded at surfaces 40 (FIG. 2) to hermetically seal off insulator 14 at that end of the insulator. Insulator 14 may be further hermetically sealed at its other end with a brazed or welded connection or coupling to the conductor housing or tube 12 portion of a single fabricated or machined conduit 54 which may also include a an end part or fitting 38 portion. The fitting portion or end part 38 may be designed for a brazed or welded connection at surface 42 to an elongated tube 43 (FIGS. 4 and 5). In general, hermetic sealing may be accomplished with brazing or welding the respective materials or components together. The housing or tube 12 and fitting 38 portions of conduit 54 may be composed of stainless steel, or other similar materials.

In FIG. 2, if for some reason cap 17 and fitting 32 portions of end part 53 and tube 12 and end part or fitting 38 portions of conduit 54 were to be fabricated or manufactured as separate components, then cap 17 and fitting 32 portions would have a hermetic braze or weld at surfaces 33, and tube 12 and end part or fitting 38 portions would have a hermetic braze or weld at surfaces 41.

The housing or tube 12 portion may surround wire 16, for example, for at least a certain insulated length of wire 16.

Wire 16 may be braided and have heat resistant (i.e., ˜1000 deg. F.) woven glass insulation. An inside diameter of the tube 12 portion may be greater than the outside diameter of wire 16 with insulation, thus resulting in some volume 22 between the tube 12 portion and wire 16 within the tube portion of conduit 54.

Volume 31 in FIG. 2 may contain air. Volume 31 is not necessarily needed for performance of assembly 18, but may be a consequence of ease of fabrication or manufacture.

The fitting 32 portion of end part 53 may have a hole 34 centered on an axis 35. Hole 34 may be aligned along axis 35 with a hole 36 in insulator 14. Holes 34 and 36 may have, but not necessarily, the same diameter.

In FIG. 2, near the end of insulator 14 opposite of the end with the cap 17 and fitting 32 portions of end part 53, there may be a stainless steel end fitting or part 38 and tube 12 portions of the single fabricated or machined conduit 54. The tube 12 portion may have a similar inside diameter slightly greater or nearly the same than the outside diameter of insulator 14. The end of insulator 14 facing volume 22 may have one of various shapes, with hole 36, often for ease of manufacture. The tube 12 portion may have a hermetic seal braze at joining surfaces 39 at insulator 14. The fitting 38 portion may have a surface 42 for attachment of elongated tube or pipe 43 (FIGS. 2 and 4). Tube 43 may be welded or brazed to surface 42 resulting in a hermetic seal between tube 43 and the end part or fitting 38 portion. The fitting 38 portion of conduit 54 may have a hole 44 centered on axis 35.

One end of conductor 16 may be electrically connected to flame rod 11 via coupling 13. The other end of conductor 16 may be connected to an electrical terminal connector 45 (as in FIG. 5). Conductor 16 may have an insulation 47 around it from electrical terminal connector 45, through elongated tube 43 (FIG. 5), fitting 38 and housing or tube 12 portions of conduit 54 (FIG. 4) and volume 22 up to the end of insulator 14 facing volume 22 (FIG. 2). An un-insulated portion of conductor 16 may go through hole 36 of insulator 14, volume 31 (if any) and hole 34 of end part 53 (FIGS. 2 and 3). An end of conductor 16 may have a hermetic seal braze or weld 21 at the end of the fitting 32 portion of end part 53. Flame rod 11 may be screwed into coupling 13 so that the threaded end of rod 11 can make electrical contact with conductor 16 through coupling 13 and end part 53.

A high temperature ceramic insulator sleeve 49 may have a hole with a diameter just so that the insulator 49 may slide on flame rod 11 towards coupling 13. Insulator 49 may be fixed to rod 11 by a mechanical interference or adhesive mechanism. High temperature ceramic insulator 49 may further be butted up to threaded coupling 13 from the flame rod 11, surround the flame rod and be extended out for a certain effective length from coupling 13 on the flame rod 11 so as to electrically insulate that portion of the flame rod.

Components of assembly 18 may be further sealed, electrically insulated, and protected from moisture with a length of external sheathing 15 (FIGS. 1, 3 and 5a). Sheathing 15 may be a polymer, an insulating coating of a lacquer-like insulating varnish having a high dielectric strength, or electrical heat shrink tubing. Sheathing 15 may be particularly applied to cover external surfaces of conduit 54, insulator 14, and end part 53. It may also be applied to coupling 13, a portion of or the entirety of insulator 49 and a portion of flame rod 11. Sheathing 15 may further cover a portion of elongated tube 43. The inner surface of sheathing 15 may create a sealing surface. Sheathing 15 may be an enhancement. Assembly 18 could operate satisfactorily without sheathing 15.

One may note scale coordinate 52 symbols X and Y for length and width dimension scaling purposes in FIG. 3. In the Figure, a ratio of X/Y may instead be greater than one (e.g., 2, 5, and so on) in that assembly 18 is proportionately longer (left and right in the Figure) relative to its width than it appears in the Figure. The particular view of FIG. 3 is for illustrative purposes.

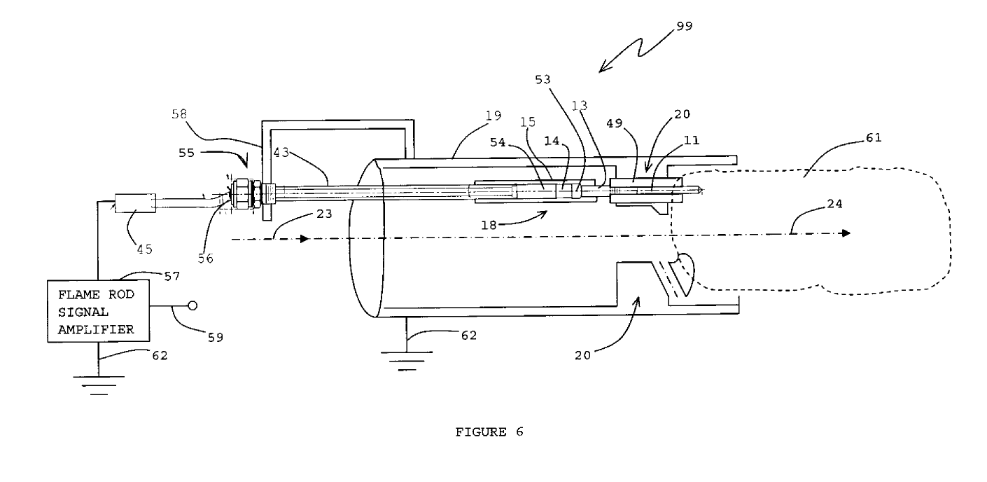

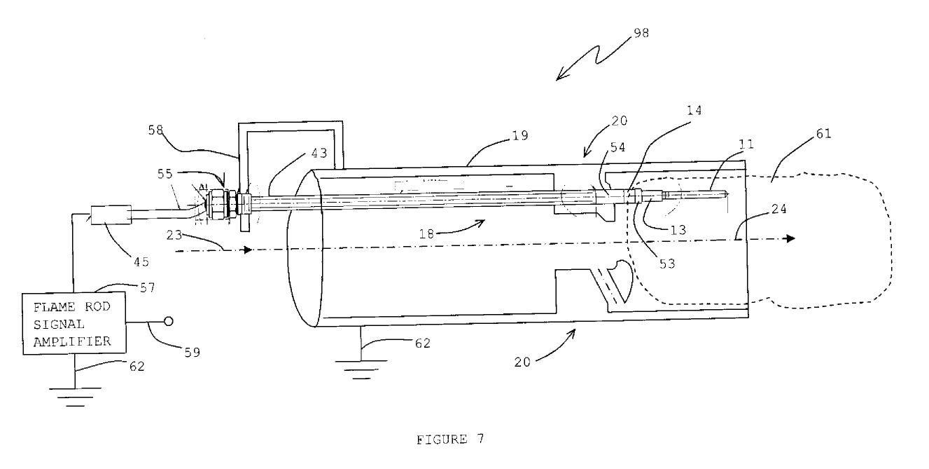

FIGS. 5 and 5a are diagrams of essentially the whole flame rod assembly 18. The assembly may be mounted with a threaded fitting mechanism 55 which may be attached to a mount (FIGS. 6 and 7) for holding assembly 18 as a portion of a larger burner assembly 99 or 98. A larger burner assembly 99 or 98 utilizing the flame rod assembly 18 may be a pilot burner for industrial, commercial or petrochemical applications such as process burners, boiler burners, flares or thermal oxidizers. Larger burner assembly 98 or 99 may also be the main burner or burners for industrial, commercial or petrochemical applications, such as process burners, boiler burners, flares or thermal oxidizers.

An end 56 of elongated tube or pipe 43 may be somewhat sealed with a material (e.g., silicone sealant) around the insulation 47 of enclosed conductor 16 inside of end 56 (FIGS. 5 and 5a). Other parts of assembly 18 shown in FIG. 5 may be described in other places of the present description.

As shown in a diagram of FIG. 6, the flame rod assembly 18 may be placed in a burner tube 19 such that conductor housing tube 43 and conductor lead wire 16 extend away from the flow restrictor 20 upstream into the incoming fuel and air mixture flowing in direction 23. A sheath 15 may cover a portion of tube 43, conduit 54, insulator 14, end part 53 and a portion or all of coupling 13. The flow restrictor or bluff body 20 may create turbulence and provide a pressure drop from position 23 to position 24. Item 20 may isolate and stabilize burner flame 61 on its downstream side. The flame rod 11 and high temperature ceramic insulator 49 may protrude through a flow restrictor 20. The flame rod 11 may protrude into the pilot burner flame 61. Air and fuel may enter from position or direction 23 and go downstream past restrictor 20 and result in a flame 61 just past the restrictor 20 toward position or direction 24 in the pilot burner tube 19. Insulator 49 may be positioned near or partially in flame 61. Insulator 49 may also have a small portion situated upstream from restrictor 20. If insulator 49 is wet or contains moisture, it may be dried quickly by flame 61. When a flame 61 is emitted by burner 19, the combustion process may create and move a field of ionized gas as part of burner flame 61.

An effect of moving an ionized gas field in the flame may result in an electrical potential or voltage potential between metal burner 19 and flame rod 11. The voltage potential may be conveyed over a carrier signal emitted from a flame amplifier 57 and carried from rod 11 via coupling 13, conductor 16, and connector 45 to a flame amplifier 57 for conditioning into a useful signal at an output 59. Assembly 18 may be secured to mount 58 that is attached and electrically connected to burner 19, with threaded mechanism 55. Burner 19, mount 58 and amplifier 57 may be connected to a common electrical ground 62.

FIG. 7 is a diagram similar to the diagram of FIG. 6 except for the makeup and position of flame rod assembly 18. End part 53 and conduit 54 may be welded or brazed to insulator 14 with a high temperature material which can withstand temperatures equal to or greater than 1500 degrees F. Such fabricated assembly does not necessarily need the ceramic sleeve 49 situated on the portion of the flame rod 11 up against coupling 13, although the sleeve may be utilized. A sheath 15 would not necessarily be used for assembly 18 in the burner arrangement 98 of FIG. 7. Assembly 18 may be positioned further into flame 61 to an extent that includes at least a portion of insulator 14 situated in the flame, in addition to the whole flame rod 11, coupling 13 and end part 53. This approach may improve the elimination of moisture and/or water in assembly 18 thereby reducing or diminishing the possibility of electrical shorts and consequent malfunction of rod assembly 18 flame detection.

The welding or brazing may be an ordinary or low temperature process for obtaining hermetic sealed connections between the components of assembly 18. This process may involve copper, silver and other like materials good for making hermetic sealed connections for applications under 1500 degrees F. On the other hand, the welding or brazing process may be a high temperature process for obtaining hermetic sealed connections between the components of assembly 18. This process may involve using alloys involving chromium, nickel and other like materials for making good hermetic sealed connections for applications under conditions at equal to or greater than 1500 degrees F. Connection of components of assembly 18 may involve brazing or welding; however, herein “brazing” may generally refer to brazing and/or welding.

In the present specification, some of the matter may be of a hypothetical or prophetic nature although stated in another manner or tense.

Although the present system has been described with respect to at least one illustrative example, many variations and modifications will become apparent to those skilled in the art upon reading the specification. It is therefore the intention that the appended claims be interpreted as broadly as possible in view of the prior art to include all such variations and modifications.

What is claimed is:

1. A flame detector assembly comprising:
an insulator;
an end part coupled to the insulator;
a flame rod connected to the end part;
a conductor situated through the insulator and connected to the end part; and
an insulator sleeve covering a portion of the flame rod.

2. The assembly of claim 1, further comprising a sheath of material covering at least the insulator and the end part.

3. The assembly of claim 1, wherein the insulator sleeve comprises a ceramic material.

4. The assembly of claim 2, wherein the material of the sheath is selected from of a group consisting of a polymer, a lacquer-like insulating varnish having a dielectric, and electrical heat shrink tubing material.

5. The assembly of claim 1, further comprising:
a conduit hermetically coupled to the insulator; and
wherein the end part is hermetically coupled to the insulator.

6. The assembly of claim 5, further comprising:
an elongated tube hermetically coupled to the conduit; and
the conductor is further situated through the elongated tube and the conduit.

7. The assembly of claim 6, further comprising a coupling for mechanically attaching the flame rod to the end part.

8. The assembly of claim 7, further comprising:
a sheath of material covering a portion of the elongated tube, the conduit, the insulator, the end part, and at least a portion of the coupling; and
wherein the material of the sheath has electrical insulating properties.

9. The assembly of claim 6, wherein:
the end part is hermetically coupled to the insulator with brazing; and
the elongated tube is hermetically coupled to the conduit with brazing.

10. The assembly of claim 9, wherein if an end of the elongated tube not coupled to the conduit is hermetically closed from an external environment, then a volume in the elongated tube, the conduit, the insulator and the end part, is hermetically sealed from the external environment.

11. The assembly of claim 10, wherein the flame rod is situated in a burner assembly at a position which exposes a portion of the sleeve covering the flame rod and the flame rod not covered by the sleeve, to a location of a flame.

12. The assembly of claim 9, wherein the brazing is for providing hermetic coupled connections for high temperature use at ≧1500 degrees F.

13. The assembly of claim 12, wherein the flame rod is situated in a burner assembly at a position which exposes the flame rod, the end part and at least a portion of the insulator to a location of a flame.

14. A flame rod assembly comprising:
a flame rod;
an end part having a first end connected to the flame rod;
an insulator having a first end hermetically coupled with a high temperature braze to a second end of the end part; and
the high temperature braze provides a hermetically sealed coupling effective at 1500° F.

15. The assembly of claim 14, further comprising:
a conduit having a first end hermetically coupled with a high temperature braze to a second end of the insulator; and
a conductor situated through a second end of the conduit, the conduit and insulator to the end part for providing an electrical connection to the flame rod.

16. A method for making a flame rod sensor comprising:
providing a flame rod;
connecting an end part to the flame rod; and
brazing an insulator to the end part; and
wherein the brazing provides a connection between the insulator and the end part which is effective at ≧1500° F.

17. The method of claim 16, wherein the connection between the insulator and the end part is a hermetic seal.

18. The method of claim 17, further comprising:
brazing a conduit to the insulator with a hermetic seal effective at ≧1500° F.;
placing a conductor through the conduit and the insulator to a connection at the end part; and
connecting the conductor to the flame rod via the end part and a mechanical coupling between the end part and the flame rod.

19. The method of claim 18, wherein the brazing involves using a material comprising chromium, nickel, and/or similar metals.

20. The method of claim 19, wherein:
the end part comprises stainless steel;
the insulator comprises a ceramic material; and
the conduit comprises stainless steel.
